(19) United States
(12) Patent Application Publication
(10) Pub. No.: US 2025/0112153 A1
(43) Pub. Date: Apr. 3, 2025

(54) VIRTUAL GROUND NET FOR PROCESS-INDUCED DAMAGE PREVENTION

(71) Applicant: Intel Corporation, Santa Clara, CA (US)

(72) Inventors: Inanc Meric, Portland, OR (US); Keun Woo Park, Hillsboro, OR (US); Jeffrey Hicks, Banks, OR (US)

(73) Assignee: Intel Corporation, Santa Clara, CA (US)

(21) Appl. No.: 18/477,838

(22) Filed: Sep. 29, 2023

(51) Int. Cl. H01L 23/528; H01L 21/768; H01L 23/48; H01L 23/522; H01L 27/092

(52) U.S. Cl. CPC H01L 23/5286; H01L 21/76898; H01L 23/481; H01L 23/5228; H01L 23/5283; H10D 84/853

(57) ABSTRACT

Integrated circuit (IC) devices and systems with virtual ground nets, and methods of forming the same, are disclosed herein. In one embodiment, an integrated circuit die includes a device layer with transistors, a first interconnect over the device layer, and a second interconnect under the device layer. Moreover, the first interconnect includes ground traces, which are electrically coupled to each other in the first interconnect or the second interconnect.

### BACKGROUND

Process-induced damage (PID) refers to damage caused by processes used to fabricate semiconductor devices. For example, during silicon wafer processing, various steps involve plasma processes that expose the wafer to plasma (e.g., for film deposition, etching). These plasma processes can cause charge to collect on metal layers and build up across dielectric layers, which may break down or degrade the quality of the dielectric layers.

### BRIEF DESCRIPTION OF THE DRAWINGS

FIG. 1 illustrates a schematic of an example integrated circuit with a virtual ground net.

FIG. 2 illustrates a cross-section of an example integrated circuit with a virtual ground net connected at the first backside metal layer.

FIG. 3 illustrates a cross-section of an example integrated circuit with a virtual ground net connected at the first frontside metal layer.

FIG. 4 illustrates a cross-section of an example integrated circuit with a virtual ground net connected at the last frontside metal layer.

FIG. 5 illustrates a flowchart for forming an integrated circuit with a virtual ground net in accordance with certain embodiments.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIGS. 8A-D are perspective views of example planar, FinFET, gate-all-around, and stacked gate-all-around transistors.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Process-induced damage (PID), which refers to damage caused by semiconductor fabrication processes, presents various challenges for semiconductor manufacturing. For example, during silicon wafer processing, various steps involve plasma processes that expose the wafer to plasma (e.g., for film deposition, etching). These plasma processes can cause charge to collect on metal layers and build up across dielectric layers, which can cause undesired dielectric breakdown. For example, during a plasma process, any existing metal on the surface of the wafer acts as an antenna, which causes charge (e.g., plasma) to accumulate on the metal. If the metal is near a dielectric, such as a gate dielectric of a transistor, or a backend metal-metal dielectric (e.g., a dielectric layer separating two metal layers), the accumulated charge on the metal may build up on the dielectric, which may break down the dielectric or degrade its quality.

Plasma PID prevention is a well-established area of semiconductor manufacturing and may be handled in various ways depending on the process technology. For example, bulk silicon technologies typically rely on tap (e.g., doped) connections to connect transistors and metals to the silicon wafer, thus creating a discharge path between the collected plasma charge and the silicon wafer. Moreover, since the silicon wafer is placed on a wafer chuck tool during fabrication, the wafer chuck connects the discharge path to ground. In this manner, the tap connections create a common node that all circuit blocks are connected to-defined as ground-which creates a defined potential difference between all nodes. However, this approach only works in bulk silicon technologies where the entire wafer is a block of silicon.

Silicon-on-insulator (SOI) technologies use a layered silicon-insulator-silicon wafer, which includes a buried oxide (BOX) insulator layer between two silicon layers or wafers. As a result, SOI technologies are unable to rely on traditional tap connections used for PID prevention in bulk silicon technologies. Thus, SOI technologies may use various alternative PID prevention solutions, such as (i) controlling the delta potential by limiting the size of the metal charge collectors (e.g., the “antenna” size for charge collection), or (ii) forming “lightning-rods” to connect nodes through the buried oxide (BOX) insulator layer into the base silicon wafer. These techniques are complicated and expensive with respect to circuit design and silicon processing.

Further, backside power delivery (BPD) technology introduces new challenges to established PID prevention solutions. For example, BPD technology uses a frontside interconnect for signaling and a backside interconnect for power delivery. During fabrication, processing is performed on the frontside of the silicon wafer first (e.g., device/transistor processing, frontside metal/interconnect processing), and then a carrier wafer is attached to the frontside of the silicon wafer and the wafers are flipped over with the carrier wafer on bottom (e.g., in the wafer chuck). The backside of the silicon wafer is then thinned and/or removed and the remaining processing on the backside is performed (e.g., backside metal/interconnect processing). Thus, during backside processing, the carrier wafer is in the wafer chuck rather than the silicon wafer, and thus tap connections to the silicon wafer are ineffective for draining charge from plasma processes.

Accordingly, this disclosure presents embodiments of integrated circuits fabricated with a virtual ground net for process-induced damage (PID) prevention, along with methods of forming the same. In particular, a virtual ground net is formed during fabrication of integrated circuits to prevent damage from plasma processing. For example, with respect to backside power technologies, all ground nets for different circuit blocks may be connected to each other before the backside interconnect is formed. In particular, the connection between the respective ground nets may be formed at one of the frontside metal layers or at the first backside metal layer. In this manner, a common voltage potential is provided across the respective ground nets, thus forming a “virtual ground,” which ensures a safe level of potential buildup due to plasma charge during backside metal processing.

The described solution provides various advantages. For example, this solution provides plasma PID protection with no additional costs for wafer fabrication and minimal changes to circuit design. Moreover, this solution can provide PID protection for process technologies that that are incompatible with traditional PID protection mechanisms (e.g., tap connections for bulk silicon), such as backside power delivery and silicon-on-insulator (SOI) technologies.

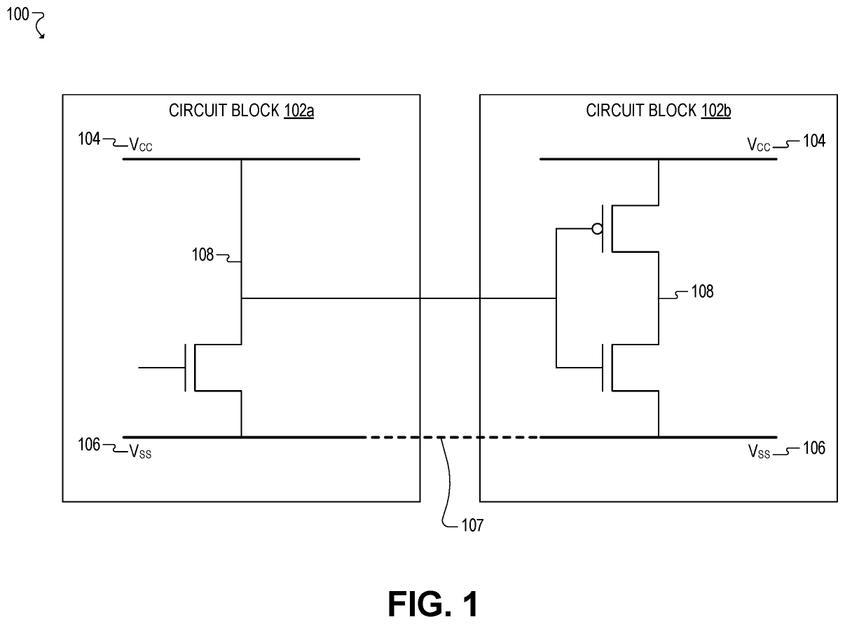

FIG. 1 illustrates a schematic of an integrated circuit (IC) 100 with a virtual ground net in accordance with certain embodiments. In the illustrated embodiment, IC 100 includes multiple circuit blocks 102a-b (e.g., separate intellectual property (IP) blocks on the same integrated circuit), and each circuit block 102a-b includes a power net (V_{CC}) 104, ground net (V_{SS}) 106, and signal net 108. Moreover, the ground nets 106 of the respective circuit blocks 102a-b are connected to each other to form a virtual ground net 107, which creates known voltage deltas on the respective circuit blocks 102a-b and enables plasma charge to flow, thus preventing plasma-induced damage during fabrication, as described below.

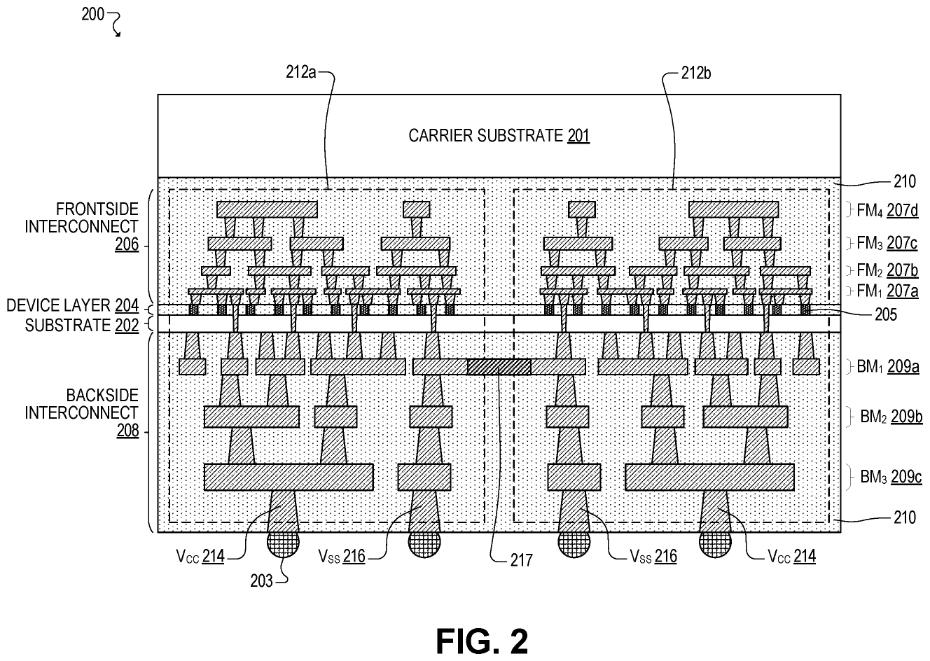

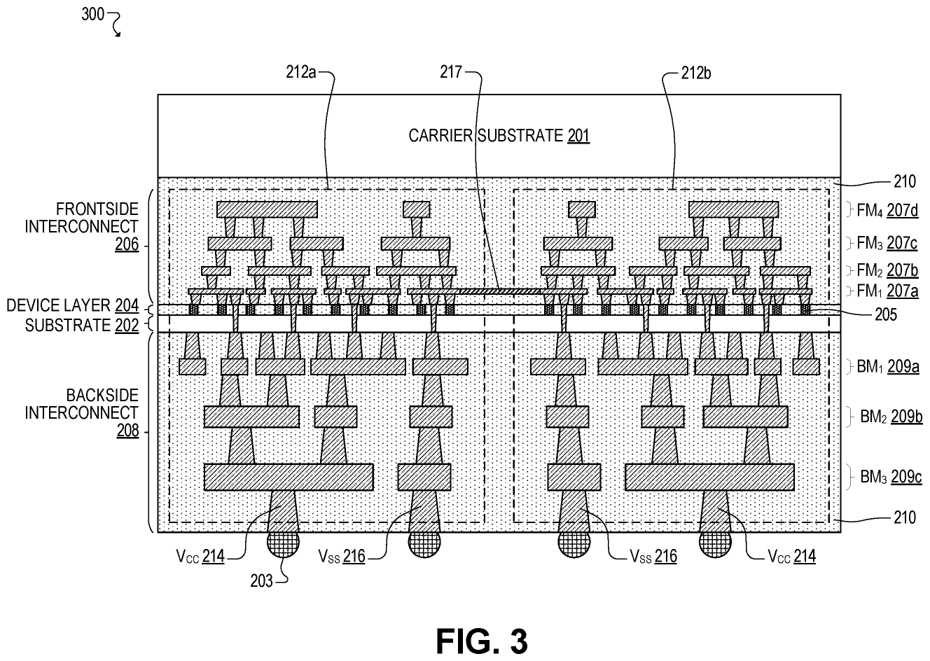

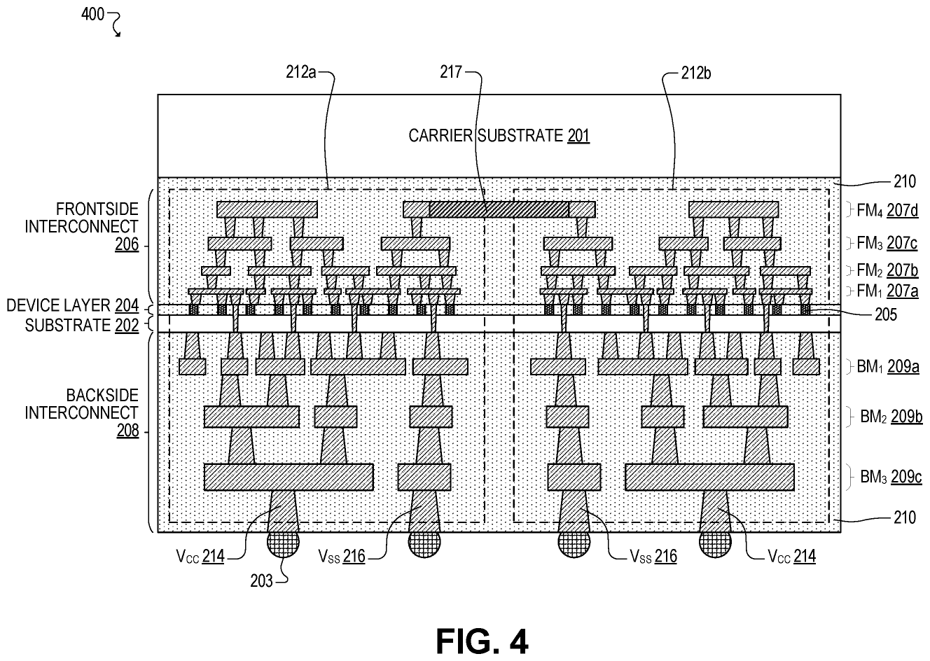

In some embodiments, this solution may be implemented as a layout design rule for process technologies with backside power delivery architectures. In particular, the design rule may require that all ground nets (V_{SS}) 106 be connected to each other at or before the first backside metal layer. For example, based on this rule, the connection 107 between the respective ground nets 106 may be formed at one of the frontside metal layers in the frontside interconnect (e.g., as shown in FIGS. 3-4), or alternatively, at the first backside metal layer in the backside interconnect (e.g., as shown in FIG. 2). Moreover, in various embodiments, the connection 107 between ground nets 106 can be made either directly by the particular metal layer, or indirectly through one or more devices such as back-to-back diodes, resistors, etc. (e.g., to filter noise from ground nets 106 of different circuit blocks 102a-b).

This design rule ensures that all ground nets 106 are connected to each other at or before the first backside metal layer in the fabrication process. In this manner, the connection 107 between ground nets 106 creates a “virtual ground” net, which ensures that all voltages are defined based on this common net.

For example, since no true physical ground connection is possible during backside processing for backside power delivery technologies, there is no ground/tap connection to the silicon wafer. Instead, this solution connects the ground nets 106 of different circuit blocks 102a-b to each other to create a common node that all circuit blocks 102a-b are connected to (e.g., a common voltage potential), which is referred to as “virtual ground.” This common node creates a defined potential difference (e.g., known voltage deltas) between the respective circuit blocks 102a-b, which enables plasma charge to flow, thus preventing plasma-induced damage from charge buildup and related yield fallout.

For example, without the virtual ground connection 107 between the respective ground nets 106, the voltage delta across the dielectric gate oxides (GOX) of the transistors is undefined. Connecting the ground nets 106 eliminates the undefined GOX voltage delta and provides a common voltage plane for protection to other backside metal traces/antennas in the power net 104.

FIG. 2 illustrates a cross-section of an integrated circuit (IC) 200 with a virtual ground net connected at the first backside metal layer in accordance with certain embodiments. In the illustrated embodiment, for example, IC 200 includes multiple circuit blocks 212a-b with power (V_{CC}) and ground (V_{SS}) nets 214, 216, along with a connection 217 between the respective ground nets 216 at the first backside metal layer (BM₁) 209a. In this manner, the respective ground nets 216 are connected to each other to form a virtual ground net, which helps prevent plasma-induced damage caused by charge buildup during fabrication, as described throughout this disclosure.

In the illustrated embodiment, IC 200 includes a thinned silicon substrate 202, a device layer 204 over the silicon substrate 202, a frontside interconnect 206 over the device layer 204, and a backside interconnect 208 under the device layer 204 and the silicon substrate 202. IC 200 also includes a carrier substrate 201 attached above the frontside interconnect 206 for structural support, along with conductive (e.g., metal) bumps 203 on the bottom surface to electrically couple IC 200 with another electronic device (e.g., an IC package, another IC die/chip, etc.).

The device layer 204 includes one or more semiconductor devices 205 such as transistors. The frontside interconnect 206 include multiple frontside metal (FM) layers (FM₁₋₄) 207a-d (e.g., for signaling), and the backside interconnect 208 includes multiple backside metal (BM) layers (BM₁₋₃) 209a-c (e.g., for power delivery and ground connections). The remaining areas are filled with one or more inter-layer dielectrics (ILDs) 210.

In the illustrated embodiment, the device layer 204 and interconnects 206, 208 collectively implement logic circuitry 205 and power (V_{CC}) 214, ground (V_{SS}) 216, and signal 218 networks for multiple circuit blocks 212a-b on IC 200.

Further, IC 200 also includes a connection 217 between the ground nets 216 of the respective circuit blocks 212a-b to form a virtual ground net, which helps prevent process-induced damage caused by plasma charge buildup during fabrication, as described throughout this disclosure. In the illustrated embodiment, the ground nets 216 are connected at the first backside metal layer (BM₁) 209a. In other embodiments, however, the ground nets 216 may be connected at one of the frontside metal layers 207a-d (e.g., as shown in FIGS. 3-4).

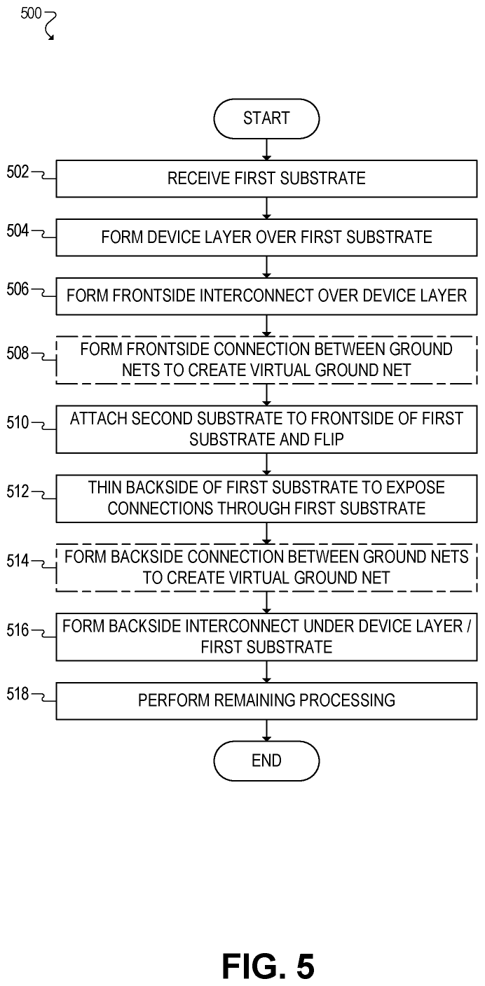

An example process flow for forming IC 200 (and ICs 300 and 400 of FIGS. 3 and 4) is described below in connection with FIG. 5.

FIG. 3 illustrates a cross-section of an integrated circuit (IC) 300 with a virtual ground net connected at the first frontside metal layer in accordance with certain embodiments. In the illustrated embodiment, IC 300 is similar to IC 200, except the virtual ground connection 217 between the respective ground nets 216 is formed at the first frontside metal layer (FM₁) 207a of the frontside interconnect 206 (e.g., rather than at the first backside metal layer (BM₁) 209a).

FIG. 4 illustrates a cross-section of an integrated circuit (IC) 400 with a virtual ground net connected at the last frontside metal layer in accordance with certain embodiments. In the illustrated embodiment, IC 400 is similar to ICs 200 and 300, except the virtual ground connection 217 between the respective ground nets 216 is formed at the last frontside metal layer (FM₄) 207d of the frontside interconnect 206 (e.g., rather than at the first backside metal layer (BM₁) 209a or the first frontside metal layer (FM₁) 207a).

In other embodiments, the virtual ground net may be connected at any of the other frontside metal layers, including the second and third frontside metal layers (FM₂, FM₃) 207b-c of ICs 200, 300, 400.

FIG. 5 illustrates a flowchart 500 for forming an integrated circuit (IC) with a virtual ground net in accordance with certain embodiments. It will be appreciated in light of the present disclosure that the illustrated process flow is only one example methodology for arriving at the example ICs shown and described throughout this disclosure (e.g., ICs 100, 200, 300, 400).

The steps of the illustrated process flow may be performed using any suitable semiconductor fabrication techniques. For example, film deposition-such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal-such as interconnect patterning, forming via openings, and shaping—may be performed using any suitable techniques, such as lithography-based patterning/masking and/or etching.

The illustrated process flow may be used to form one or more IC dies that respectively include a device layer along with frontside and backside interconnects above and below the device layer (e.g., for signaling and power delivery). In some embodiments, the device layer and interconnects may collectively implement logic circuitry and signal, power, and ground nets for one or more circuits or circuit blocks on the respective IC dies. Moreover, the respective ground nets may be connected to each other at one of the frontside metal layers, or at the first backside metal layer, to create a virtual ground net, which helps prevent process-induced damage during fabrication, as described throughout this disclosure.

The flowchart begins at block 502 by receiving a first substrate. In some embodiments, the first substrate may be a wafer or panel and may include silicon (Si). Further, the first substrate may be pre-patterned with one or more through-silicon vias (TSVs), or alternatively, the first substrate may be received without any pre-patterned TSVs and one or more TSVs may be subsequently formed in the substrate.

The flowchart then proceeds to block 504 to form a device layer over the first substrate. The device layer may include one or more devices, such as transistors (e.g., CMOS, PMOS, NMOS), to implement the logic of the respective circuits or circuit blocks. Moreover, one or more vias may be formed through the device layer to form electrical connections to the TSVs in the first substrate.

The flowchart then proceeds to block 506 to form a first interconnect over the device layer (e.g., on the frontside of the first substrate), which may be referred to as the frontside interconnect. For example, multiple conductive (e.g., metal) layers may be formed over the device layer, along with intervening dielectric layers separating the conductive layers. The conductive layers, which may also be referred to as metal layers, may be made of one or more electrically-conductive materials that include one or more metals (e.g., any of the metals/alloys described throughout this disclosure). Further, the dielectric layers may include one or more dielectric materials (e.g., any of the dielectric materials described throughout this disclosure).

Moreover, conductive traces may be patterned (e.g., etched) in the frontside conductive layers, and vias may be formed between the conductive layers (e.g., through the intervening dielectric layers) to electrically couple traces in different conductive layers. The conductive traces and vias patterned in and between the frontside conductive layers may collectively form one or more signal, power, and/or ground nets for the respective circuits or circuit blocks (e.g., networks of conductive traces that provide signaling, power, and ground connections).

The signal nets (e.g., VIN, VOUT) may include one or more conductive traces used for signaling (e.g., electrical connections between inputs and outputs of devices/transistors in the device layer), which may also be referred to as signal traces or signal routing.

The power nets (e.g., V_{CC}, V_{DD}) may include one or more conductive traces for delivering power (e.g., electrical connections between the device layer and one or more power supply terminals), which may also be referred to as power traces or power routing. Further, the power nets in the frontside interconnect may be connected to one or more corresponding power nets formed in the backside interconnect (e.g., as described below with respect to block 516).

The ground nets (e.g., V_{SS}) may include one or more conductive traces for providing ground connections (e.g., electrical connections between the device layer and one or more physical or virtual ground/reference terminals), which may also be referred to as ground traces or ground routing. Further, the ground nets in the frontside interconnect may be connected to one or more corresponding ground nets formed in the backside interconnect (e.g., as described below with respect to block 516).

The flowchart may then proceed to block 508 to optionally form a frontside connection between the respective ground nets (V_{SS}) to create a virtual ground net. For example, the virtual ground net may be created by connecting the respective ground nets to each other at any of the frontside metal layers during fabrication of the frontside interconnect (e.g., at the first frontside metal layer closest to the device layer, at the last frontside metal layer furthest from the device layer, or at any intervening frontside metal layer between the first and last frontside metal layers). Further, in some embodiments, the ground nets may be electrically coupled to each other through one or more resistors or diodes.

Alternatively, this step may be omitted, and the virtual ground net may be created by forming a backside connection between the respective ground nets (V_{SS}), as described below with respect to block 514. For example, the virtual ground net may be created by connecting the respective ground nets to each other at the first backside metal layer during fabrication of the backside interconnect.

In particular, since the ground nets are not connected to a ground terminal or other ground reference point during fabrication of the backside interconnect, process-induced damage may occur, such as dielectric breakdown caused by charge buildup from plasma processes. Thus, before fabricating the backside interconnect, the respective ground nets may be connected to each other to form a virtual ground net, which helps prevent process-induced damage during fabrication of the backside interconnect. Accordingly, the virtual ground net may be formed by connecting the respective ground nets at any of the frontside metal layers (e.g., as described above with respect to block 508), or alternatively, at the first backside metal layer (e.g., as described below with respect to block 514).

The flowchart then proceeds to block 510 to attach or bond a second substrate to the frontside of the first substrate (e.g., over the frontside interconnect) and then flip the first substrate over. The second substrate may be referred to as a carrier substrate (e.g., a silicon carrier wafer or panel).

The flowchart then proceeds to block 512 to thin (e.g., grind) the backside of the first substrate to expose the connections (e.g., TSVs) formed in the first substrate.

The flowchart may then proceed to block 514 to optionally form a backside connection between the respective ground nets (V_{SS}) to create a virtual ground net. For example, as described above with respect to block 508, the virtual ground net may be created by connecting the respective ground nets to each other at any frontside metal layer or at the first backside metal layer. Thus, in embodiments where the virtual ground net is created using a backside connection, at block 514, a connection is formed between the respective ground nets at the first backside metal layer (e.g., the backside metal layer closest to the device layer) during fabrication of the backside interconnect.

For example, a dielectric layer may be formed below the device layer and the first substrate, and the first backside metal layer may be formed below the dielectric layer. Moreover, conductive traces may be patterned (e.g., etched) in the first backside metal layer, and vias may be formed through the dielectric layer to the vias in the first substrate and device layer, thus electrically coupling the traces in first backside metal layer to the ground nets in the frontside interconnect. In this manner, the ground nets of the respective circuits or circuit blocks are electrically coupled to each other in the first metal layer of the backside interconnect. Further, in some embodiments, the ground nets may be electrically coupled to each other through one or more resistors or diodes.

The flowchart then proceeds to block 516 to form a second interconnect under the device layer and the first substrate (e.g., on the backside of the first substrate), which may be referred to as the backside interconnect. If the first backside metal layer was formed to connect the respective ground nets to each other at block 514, then the remaining backside metal layers in the backside interconnect may be formed at block 516. However, if the respective ground nets were connected to each other at one of the frontside metal layers at block 508, then all backside metal layers in the backside interconnect may be formed at block 516.

For example, multiple conductive (e.g., metal) layers may be formed below the device layer and first substrate (and below the first backside metal layer, if formed at block 514), along with intervening dielectric layers separating the conductive layers. The conductive layers, which may also be referred to as metal layers, may be made of one or more electrically-conductive materials that include one or more metals (e.g., any of the metals/alloys described throughout this disclosure). Further, the dielectric layers may include one or more dielectric materials (e.g., any of the dielectric materials described throughout this disclosure).

Moreover, conductive traces may be patterned (e.g., etched) in the backside conductive layers, and vias may be formed between the conductive layers (e.g., through the intervening dielectric layers) to electrically couple traces in different conductive layers. The conductive traces and vias patterned in and between the backside conductive layers may collectively form one or more backside power and/or ground nets for the respective circuits or circuit blocks (e.g., networks of conductive traces that provide power and ground connections). For example, the backside power and ground nets may electrically couple the corresponding frontside power and ground nets to one or more backside power supply terminals and ground terminals, respectively (e.g., through the vias in the first substrate and device layer).

In this manner, the backside interconnect is electrically coupled to the frontside interconnect (e.g., through the vias in the first substrate and device layer) to provide power delivery and ground connections. Further, a virtual ground net is created by electrically coupling the respective ground nets to each other at any of the frontside metal layers in the frontside interconnect, or at the first backside metal layer in the backside interconnect, to help prevent process-induced damage during fabrication.

The flowchart then proceeds to block 518 to perform any remaining processing, such as inter-layer dielectric (ILD) filling, planarization, interconnect bump formation, etc. In wafer or panel process flows, the completed wafer or panel may be diced to singulate the IC dies on the wafer or panel. The singulated IC dies may then be incorporated into an IC package, circuit board, electronic device, system, etc.

At this point, the flowchart may be complete. In some embodiments, however, the flowchart may restart and/or certain blocks may be repeated. For example, in some embodiments, the flowchart may restart at block 502 to continue forming one or more ICs with the same or similar design.

### EXAMPLE EMBODIMENTS

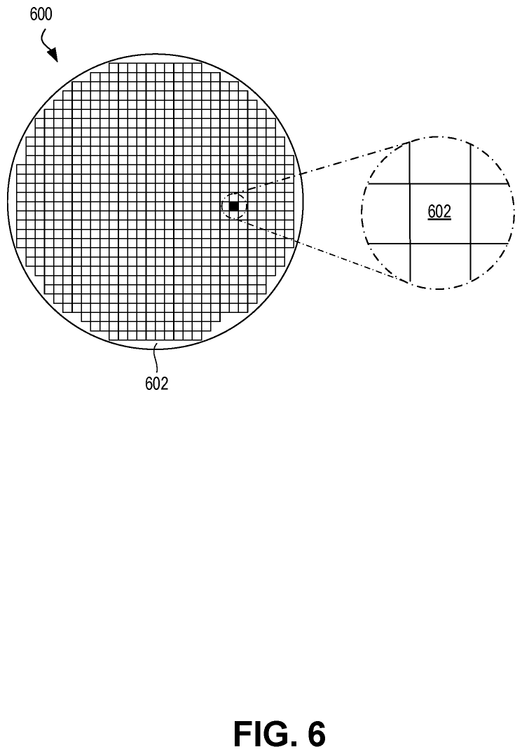

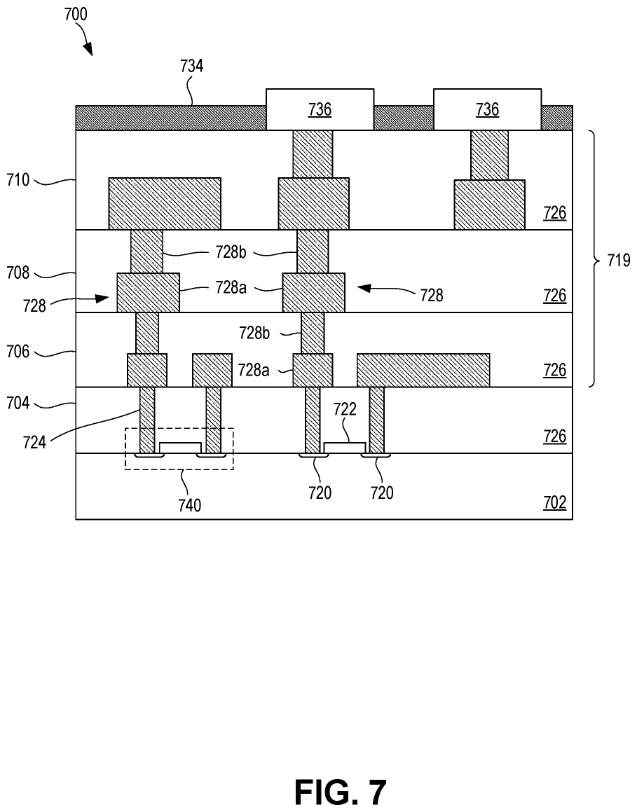

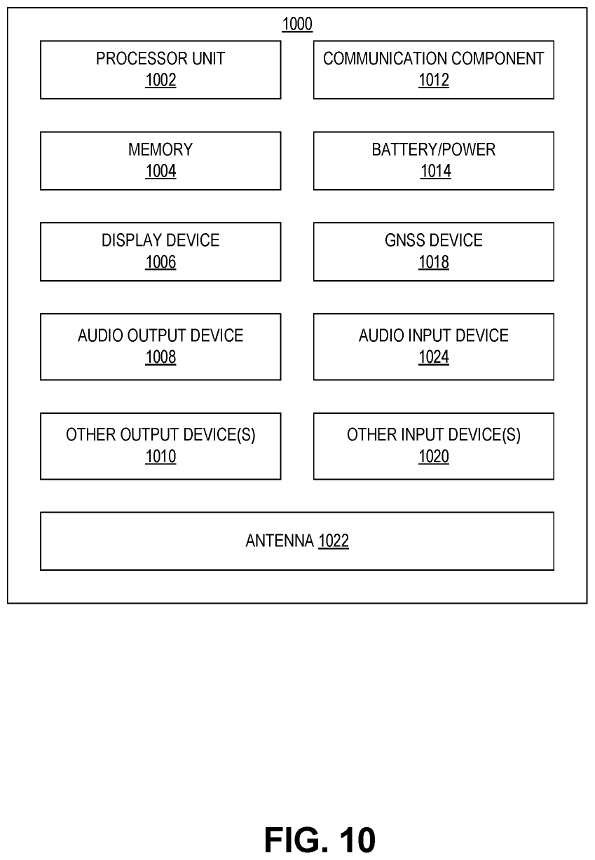

FIG. 6 is a top view of a wafer 600 and dies 602 that may be included in, or may include, any of the embodiments disclosed herein. In some embodiments, for example, the wafer 600 may include dies 602 formed with virtual ground nets (e.g., IC dies 100, 200, 300, 400). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies disclosed herein. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 1002 of FIG. 10) or other logic that is configured to store information in the memory devices or execute instructions stored in the memory array. Various ones of the microelectronic assemblies disclosed herein may be manufactured using a die-to-wafer assembly technique in which some dies are attached to a wafer 600 that include others of the dies, and the wafer 600 is subsequently singulated.

FIG. 7 is a cross-sectional side view of an integrated circuit device 700 that may be included in any of the embodiments disclosed herein (e.g., in any of the dies, such as IC dies 100, 200, 300, 400). One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

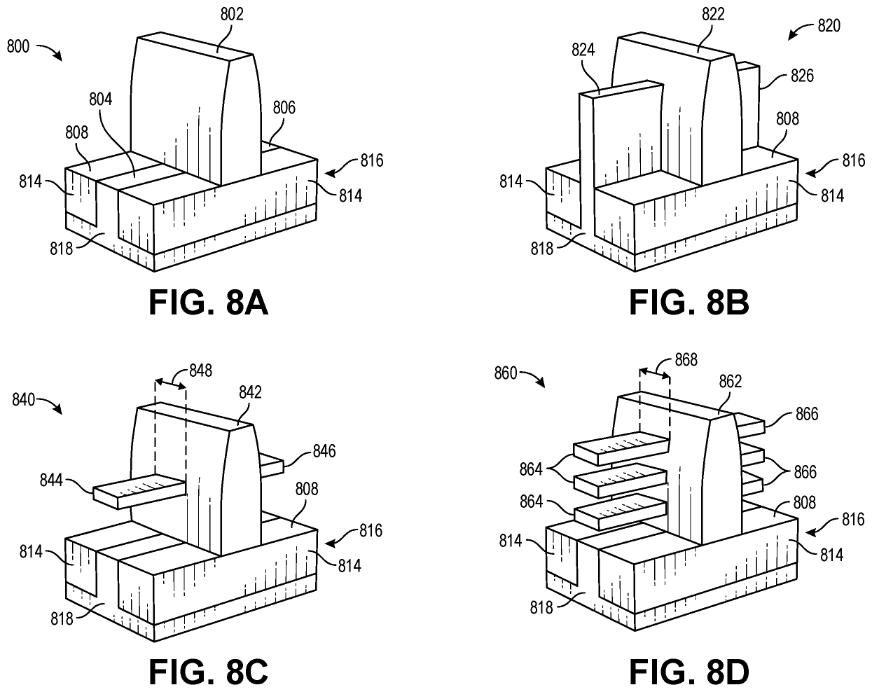

FIGS. 8A-D are simplified perspective views of example planar, FinFET, gate-all-around, and stacked gate-all-around transistors. In some embodiments, these transistors may be included in integrated circuits (ICs) with virtual ground nets (e.g., IC dies 100, 200, 300, 400). The transistors illustrated in FIGS. 8A-8D are formed on a substrate 816 having a surface 808. Isolation regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 828. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor 840 comprising a gate 842 that controls current flow between a source region 844 and a drain region 846. The transistor 840 is non-planar in that the source region 844 and the drain region 846 are elevated from the substrate surface 828.

FIG. 8D is a perspective view of a GAA transistor 860 comprising a gate 862 that controls current flow between multiple elevated source regions 864 and multiple elevated drain regions 866. The transistor 860 is a stacked GAA transistor as the gate controls the flow of current between multiple elevated S/D regions stacked on top of each other. The transistors 840 and 860 are considered gate-all-around transistors as the gates encompass all sides of the semiconductor portions that extends from the source regions to the drain regions. The transistors 840 and 860 can alternatively be referred to as nanowire, nanosheet, or nanoribbon transistors depending on the width (e.g., widths 848 and 868 of transistors 840 and 860, respectively) of the semiconductor portions extending through the gate.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components. The conductive contacts 736 may serve as any of the conductive contacts described throughout this disclosure.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736. These additional conductive contacts may serve as any of the conductive contacts described throughout this disclosure.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. These additional conductive contacts may serve as any of the conductive contacts described throughout this disclosure. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

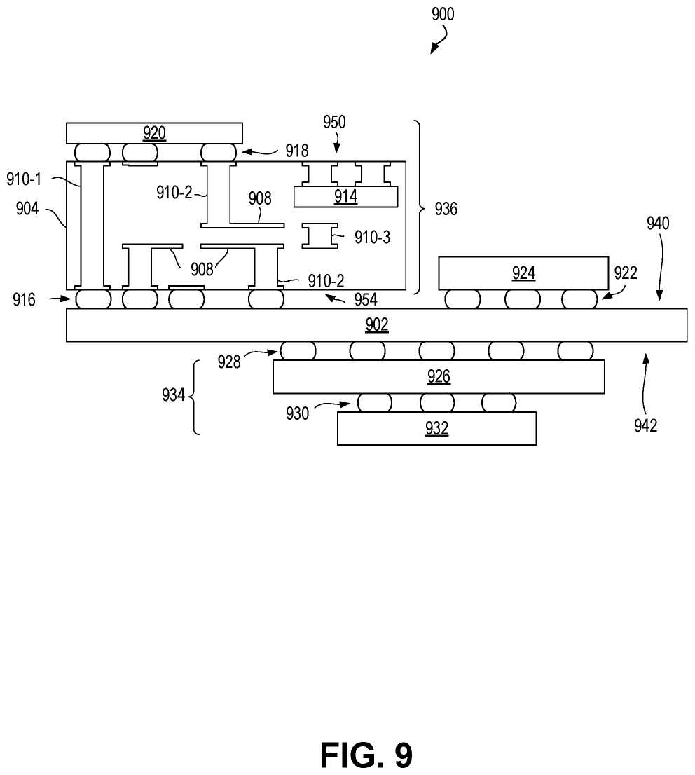

FIG. 9 is a cross-sectional side view of an integrated circuit device assembly 900 that may include any of the embodiments disclosed herein (e.g., one or more integrated circuits with a virtual ground net). In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable ones of the components of the electrical device 1000 may include one or more of the integrated circuits with virtual ground nets (e.g., ICs 100, 200, 300, 400), integrated circuit device assemblies 900, integrated circuit components 920, integrated circuit devices 700, or integrated circuit dies 602 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include other output device(s) 1010 (or corresponding interface circuitry, as discussed above). Examples of the other output device(s) 1010 may include an audio codec, a video codec, a printer, a wired or wireless transmitter for providing information to other devices, or an additional storage device.

The electrical device 1000 may include other input device(s) 1020 (or corresponding interface circuitry, as discussed above). Examples of the other input device(s) 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an integrated circuit die, comprising: a device layer, wherein the device layer comprises a plurality of transistors; a first interconnect over the device layer, wherein the first interconnect comprises a plurality of ground traces; and a second interconnect under the device layer, wherein the second interconnect is electrically coupled to the first interconnect; wherein the ground traces are electrically coupled to each other in at least one of the first interconnect or the second interconnect.

Example 2 includes the integrated circuit die of Example 1, wherein: the second interconnect comprises a plurality of conductive layers, wherein the plurality of conductive layers include a first conductive layer closest to the device layer; and the ground traces are electrically coupled to each other in the first conductive layer.

Example 3 includes the integrated circuit die of Example 1, wherein: the first interconnect further comprises a plurality of conductive layers; and the ground traces are electrically coupled to each other in one of the plurality of conductive layers.

Example 4 includes the integrated circuit die of Example 3, wherein: the plurality of conductive layers include a first conductive layer closest to the device layer; and the ground traces are electrically coupled to each other in the first conductive layer.

Example 5 includes the integrated circuit die of Example 3, wherein: the plurality of conductive layers include a last conductive layer furthest from the device layer; and the ground traces are electrically coupled to each other in the last conductive layer.

Example 6 includes the integrated circuit die of any of Examples 1-5, wherein: the first interconnect further comprises one or more signal traces electrically coupled to one or more of the transistors; and the second interconnect comprises one or more power traces electrically coupled to one or more power supply terminals.

Example 7 includes the integrated circuit die of any of Examples 1-6, wherein: the first interconnect is on a frontside of the integrated circuit die; and the second interconnect is on a backside of the integrated circuit die.

Example 8 includes the integrated circuit die of any of Examples 1-7, wherein the ground traces are electrically coupled to each other through one or more resistors or diodes.

Example 9 includes the integrated circuit die of any of Examples 1-8, further comprising one or more vias through the device layer, wherein the first and second interconnects are electrically coupled through the one or more vias.

Example 10 includes the integrated circuit die of any of Examples 1-9, further comprising a plurality of circuit blocks, wherein individual circuit blocks comprise one or more of the transistors and a ground net, wherein the ground net comprises one or more of the ground traces, and wherein the ground nets of the plurality of circuit blocks are electrically coupled to each other.

Example 11 includes an electronic device, comprising: a plurality of transistors; a first interconnect above the transistors, wherein the first interconnect comprises a plurality of ground nets; and a second interconnect below the transistors, wherein the second interconnect comprises a plurality of conductive layers, wherein the ground nets are electrically coupled to each other in a first conductive layer of the plurality of conductive layers, wherein the first conductive layer is closest to the transistors.

Example 12 includes the electronic device of Example 11, further comprising a plurality of circuits, wherein individual circuits comprise one or more of the transistors and one or more of the ground nets, wherein the ground nets of the respective circuits are electrically coupled to each other in the first conductive layer of the second interconnect.

Example 13 includes the electronic device of any of Examples 11-12, wherein: the first interconnect further comprises one or more first conductive traces electrically coupled to one or more of the transistors; and the second interconnect further comprises one or more second conductive traces electrically coupled to one or more power supply terminals.

Example 14 includes the electronic device of any of Examples 11-13, wherein the ground nets are further electrically coupled to a ground terminal.

Example 15 includes the electronic device of any of Examples 11-14, wherein the ground nets are electrically coupled to each other through one or more resistors or diodes.

Example 16 includes the electronic device of any of Examples 11-15, wherein the first and second interconnects are electrically coupled by one or more through-silicon vias.

Example 17 includes a method, comprising: receiving a substrate, wherein the substrate comprises silicon; forming a device layer over the substrate, wherein the device layer comprises a plurality of transistors; forming a first interconnect over the device layer, wherein the first interconnect comprises a plurality of ground traces; and forming a second interconnect under the device layer, wherein the second interconnect is electrically coupled to the first interconnect; wherein the ground traces are electrically coupled to each other in at least one of the first interconnect or the second interconnect.

Example 18 includes the method of Example 17, wherein forming the second interconnect under the device layer comprises: forming a first conductive layer under the device layer; and forming one or more conductive traces in the first conductive layer, wherein the one or more conductive traces electrically couple the ground traces in the first interconnect.

Example 19 includes the method of Example 17, wherein forming the first interconnect over the device layer comprises: forming a plurality of conductive layers over the device layer; and forming the ground traces in one or more of the conductive layers, wherein the ground traces are electrically coupled to each other in at least one of the conductive layers.

Example 20 includes the method of any of Examples 17-19, wherein the substrate is a first substrate, and wherein the method further comprises: attaching a second substrate over the first interconnect; and thinning the first substrate before forming the second interconnect.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform comprising dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. An integrated circuit die, comprising:
a device layer, wherein the device layer comprises a plurality of transistors;
a first interconnect over the device layer, wherein the first interconnect comprises a plurality of ground traces; and
a second interconnect under the device layer, wherein the second interconnect is electrically coupled to the first interconnect;
wherein the ground traces are electrically coupled to each other in at least one of the first interconnect or the second interconnect.

2. The integrated circuit die of claim 1, wherein:
the second interconnect comprises a plurality of conductive layers, wherein the plurality of conductive layers include a first conductive layer closest to the device layer; and
the ground traces are electrically coupled to each other in the first conductive layer.

3. The integrated circuit die of claim 1, wherein:
the first interconnect further comprises a plurality of conductive layers; and
the ground traces are electrically coupled to each other in one of the plurality of conductive layers.

4. The integrated circuit die of claim 3, wherein:
the plurality of conductive layers include a first conductive layer closest to the device layer; and
the ground traces are electrically coupled to each other in the first conductive layer.

5. The integrated circuit die of claim 3, wherein:
the plurality of conductive layers include a last conductive layer furthest from the device layer; and
the ground traces are electrically coupled to each other in the last conductive layer.

6. The integrated circuit die of claim 1, wherein:
the first interconnect further comprises one or more signal traces electrically coupled to one or more of the transistors; and
the second interconnect comprises one or more power traces electrically coupled to one or more power supply terminals.

7. The integrated circuit die of claim 6, wherein:
the first interconnect is on a frontside of the integrated circuit die; and
the second interconnect is on a backside of the integrated circuit die.

8. The integrated circuit die of claim 1, wherein the ground traces are electrically coupled to each other through one or more resistors or diodes.

9. The integrated circuit die of claim 1, further comprising one or more vias through the device layer, wherein the first and second interconnects are electrically coupled through the one or more vias.

10. The integrated circuit die of claim 1, further comprising a plurality of circuit blocks, wherein individual circuit blocks comprise one or more of the transistors and a ground net, wherein the ground net comprises one or more of the ground traces, and wherein the ground nets of the plurality of circuit blocks are electrically coupled to each other.

11. An electronic device, comprising:
a plurality of transistors;
a first interconnect above the transistors, wherein the first interconnect comprises a plurality of ground nets; and
a second interconnect below the transistors, wherein the second interconnect comprises a plurality of conductive layers, wherein the ground nets are electrically coupled to each other in a first conductive layer of the plurality of conductive layers, wherein the first conductive layer is closest to the transistors.

12. The electronic device of claim 11, further comprising a plurality of circuits, wherein individual circuits comprise one or more of the transistors and one or more of the ground nets, wherein the ground nets of the respective circuits are electrically coupled to each other in the first conductive layer of the second interconnect.

13. The electronic device of claim 11, wherein:
the first interconnect further comprises one or more first conductive traces electrically coupled to one or more of the transistors; and
the second interconnect further comprises one or more second conductive traces electrically coupled to one or more power supply terminals.

14. The electronic device of claim 11, wherein the ground nets are further electrically coupled to a ground terminal.

15. The electronic device of claim 11, wherein the ground nets are electrically coupled to each other through one or more resistors or diodes.

16. The electronic device of claim 11, wherein the first and second interconnects are electrically coupled by one or more through-silicon vias.

17. A method, comprising:
receiving a substrate, wherein the substrate comprises silicon;
forming a device layer over the substrate, wherein the device layer comprises a plurality of transistors;
forming a first interconnect over the device layer, wherein the first interconnect comprises a plurality of ground traces; and
forming a second interconnect under the device layer, wherein the second interconnect is electrically coupled to the first interconnect;
wherein the ground traces are electrically coupled to each other in at least one of the first interconnect or the second interconnect.

18. The method of claim 17, wherein forming the second interconnect under the device layer comprises:
forming a first conductive layer under the device layer; and
forming one or more conductive traces in the first conductive layer, wherein the one or more conductive traces electrically couple the ground traces in the first interconnect.

19. The method of claim 17, wherein forming the first interconnect over the device layer comprises:
forming a plurality of conductive layers over the device layer; and
forming the ground traces in one or more of the conductive layers, wherein the ground traces are electrically coupled to each other in at least one of the conductive layers.

20. The method of claim 17, wherein the substrate is a first substrate, and wherein the method further comprises:
attaching a second substrate over the first interconnect; and
thinning the first substrate before forming the second interconnect.
